(19) United States
(12) Patent Application Publication
(10) Pub. No.: US 2026/0121628 A1
(43) Pub. Date: Apr. 30, 2026

(54) DML DRIVER

(71) Applicant: Nippon Telegraph and Telephone Corporation, Tokyo (JP)

(72) Inventor: Toshiki Kishi, Tokyo (JP)

(21) Appl. No.: 18/836,700

(22) PCT Filed: Apr. 11, 2022
(86) PCT No.: PCT/JP2022/017482

§ 371 Date: Aug. 7, 2024

(51) Int. Cl. H03K 17/06; H01S 5/042; H03K 17/687

(52) U.S. Cl. CPC H03K 17/063; H01S 5/0427; H03K 17/6872

(57) ABSTRACT

A DML driver includes a PMOS transistor, an NMOS transistor, an inductor, a resistor, and an optical waveform compensation function unit connected between a source of the NMOS transistor and the ground. The optical waveform compensation function unit includes an NMOS transistor, an inductor, a capacitor, and a resistor.

### CROSS-REFERENCE TO RELATED APPLICATIONS

This application is a national phase entry of PCT Application No. PCT/JP2022/017482, filed on Apr. 11, 2022, which application is hereby incorporated herein by reference.

### TECHNICAL FIELD

The present invention relates to a technique for driving a directly modulated laser (DML), and particularly to a DML driver having a frequency peaking function and an optical waveform compensation function.

### BACKGROUND

In recent years, the traffic volume of communication around the world has been increasing year by year due to significant development of a social networking services (SNS). In the future, a further increase in traffic volume is expected due to development of the Internet of Things (IoT) and cloud computing technology, and in order to support a huge traffic volume, it is required to increase a communication capacity inside and outside a data center.

With the increase in capacity, standardization of 100 Gigabit Ethernet (registered trademark), which is a main standard element of a network, has currently completed, and standardization of 400 Gigabit Ethernet (registered trademark) aimed at further increasing capacity is being discussed. For the purpose of application to 400 GbE, a driver using DML has attracted attention from the viewpoint of low power consumption (see Non Patent Literature 1).

FIG. 11 is a circuit diagram illustrating a configuration of a conventional DML driver. The DML driver includes a PMOS transistor M₁ₚ having a gate connected to a bias voltage V₂, a source connected to a power supply voltage V₁, and a drain connected to an anode of a laser diode (LD) 1, an NMOS transistor M₁ₙ having a gate to which the modulation signal Vᵢₙ is input, and a source connected to ground, an NMOS transistor M₂ₙ having a gate connected to a bias voltage V₃, a drain connected to the drain of a PMOS transistor M₁ₙ and the anode of the LD 1, and a source connected to the drain of the NMOS transistor M₁ₙ, and a resistor Rᵢₙ having one end connected to the bias voltage V₄, and the other end connected to the gate of the NMOS transistor M₁ₙ.

The NMOS transistors M₁ₙ and M₂ₙ are cascode-connected, and by being cascode-connected, the frequency characteristics are improved as compared with the case of the NMOS transistor M₁ₙ alone. Even when the operating voltage of the LD 1 exceeds the withstand voltage of the NMOS transistor alone, the LD 1 is divided by the cascode connection, so that breakdown of the withstand voltage of the NMOS transistors M₁ₙ and M₂ₙ can be prevented. The resistor Rᵢₙ is a resistor for impedance matching.

As illustrated in FIG. 11, in the configuration of the conventional driver circuit, since the driver unit does not have a function of compensating for the optical output waveform of the LD, there is a problem that the optical waveform output from the transmission front end including the DML driver and the LD depends on the optical output waveform of the LD itself.

### CITATION LIST

### Non Patent Literature

Non Patent Literature 1: T. Kishi et al., “A 137-mW,4 ch×25-Gbps low-power compact transmitter flip-chip-bonded 1.3-μm LD-array-on-Si”, In Proceedings of the Optical Fiber Communication Conference and Exhibition, 2018, Paper M2D.2.

### SUMMARY

### Technical Problem

Embodiments of the present invention have been made to solve the above problems, and an object thereof is to provide a DML driver capable of shaping a light output waveform.

### Solution to Problem

A DML driver of embodiments of the present invention includes a first transistor having a gate or base connected to a first bias voltage, a source or emitter connected to a first power supply voltage, and a drain or collector connected to an anode of a laser diode, a second transistor having a drain or a collector connected to an anode of the laser diode, a first inductor to which a modulation signal is input at one end, and the other end of the first inductor being connected to a gate or a base of the second transistor, a first resistor having one end connected to a second bias voltage and the other end connected to one end of the first inductor, and an optical waveform compensation function unit connected between a source or an emitter of the second transistor and a second power supply voltage, in which the optical waveform compensation function unit includes a third transistor in which a control voltage is input to a gate or a base, a drain or a collector is connected to a source or an emitter of the second transistor, and a source or an emitter is connected to the second power supply voltage, a second inductor having one end connected to a drain or a collector of the third transistor and the other end connected to the second power supply voltage, a first capacitor having one end connected to a drain or a collector of the third transistor, a second capacitor having one end connected to a drain or a collector of the third transistor and the other end connected to the second power supply voltage, and a second resistor having one end connected to the other end of the first capacitor and the other end connected to the second power supply voltage.

In addition, one configuration example of the DML driver of embodiments of the present invention further includes a fourth transistor having a gate or base connected to a third bias voltage and cascode-connected between an anode of the laser diode and a drain or collector of the second transistor.

In addition, one configuration example of the DML driver of embodiments of the present invention further includes a fifth transistor having a gate or base connected to a fourth bias voltage and cascode-connected between a drain or collector of the first transistor and an anode of the laser diode.

Furthermore, a DML driver of embodiments of the present invention includes a first transistor having a gate or base connected to a first bias voltage, a source or emitter connected to a first power supply voltage, and a drain or collector connected to an anode of a laser diode, a second transistor having a gate or base connected to a second bias voltage, a third transistor cascode-connected between an anode of the laser diode and a drain or a collector of the second transistor, a first inductor to which a modulation signal is input at one end, and the other end of the first inductor being connected to a gate or a base of the third transistor, a first resistor having one end connected to a third bias voltage and the other end connected to one end of the first inductor, and an optical waveform compensation function unit connected between a source or an emitter of the second transistor and a second power supply voltage, in which the optical waveform compensation function unit includes a fourth transistor in which a control voltage is input to a gate or a base, a drain or a collector is connected to a source or an emitter of the second transistor, and a source or an emitter is connected to the second power supply voltage, a second inductor having one end connected to a drain or a collector of the fourth transistor and the other end connected to the second power supply voltage, a first capacitor having one end connected to a drain or a collector of the fourth transistor, a second capacitor having one end connected to a drain or a collector of the fourth transistor and the other end connected to the second power supply voltage, and a second resistor having one end connected to the other end of the first capacitor and the other end connected to the second power supply voltage.

In addition, one configuration example of the DML driver of embodiments of the present invention further includes a fifth transistor having a gate or base connected to a fourth bias voltage and cascode-connected between a drain or collector of the first transistor and an anode of the laser diode.

In addition, one configuration example of the DML driver of embodiments of the present invention further includes a third capacitor having one end connected to the first power supply voltage and a third resistor having one end connected to the other end of the third capacitor and the other end connected to a drain or a collector of the first transistor.

In addition, one configuration example of the DML driver of embodiments of the present invention further includes a third resistor inserted between a source or an emitter of the second transistor and the optical waveform compensation function unit.

In addition, one configuration example of the DML driver of embodiments of the present invention further includes a third capacitor connected in parallel with the third resistor.

### Advantageous Effects

According to embodiments of the present invention, the frequency peaking function can be realized by connecting the first inductor in series to the gate of the transistor to which the modulation signal is input, and the band of the LD can be compensated for. Further, in embodiments of the present invention, by providing an optical waveform compensation function unit, an Electrical-to-Optical (EO) frequency characteristic and a group delay characteristic of a transmission front end configured by a DML driver and an LD can be improved, and an optical output waveform can be shaped.

### BRIEF DESCRIPTION OF THE DRAWINGS

FIG. 1 is a circuit diagram illustrating a configuration of a DML driver according to a first example of the present invention.

FIG. 2 is a diagram illustrating a result of obtaining EO response characteristics of a DML driver and an LD by simulation for a conventional configuration and the first example of the present invention.

FIG. 3 is a diagram illustrating a result of obtaining group delay characteristics of the DML driver and the LD by simulation for the conventional configuration and the first example of the present invention.

FIGS. 4A and 4B are diagrams illustrating optical output waveforms of LDs in the conventional configuration and the first example of the present invention.

FIG. 5 is a circuit diagram illustrating a configuration of a DML driver according to a second example of the present invention.

FIG. 6 is a circuit diagram illustrating a configuration of a DML driver according to a third example of the present invention.

FIG. 7 is a circuit diagram illustrating a configuration of a DML driver according to a fourth example of the present invention.

FIG. 8 is a circuit diagram illustrating another configuration of the DML driver according to the fourth example of the present invention.

FIG. 9 is a circuit diagram illustrating a configuration of a DML driver according to a fifth example of the present invention.

FIG. 10 is a circuit diagram illustrating a configuration of a DML driver according to a sixth example of the present invention.

FIG. 11 is a circuit diagram illustrating a configuration of a conventional DML driver.

### DETAILED DESCRIPTION OF ILLUSTRATIVE EMBODIMENTS

### First Example

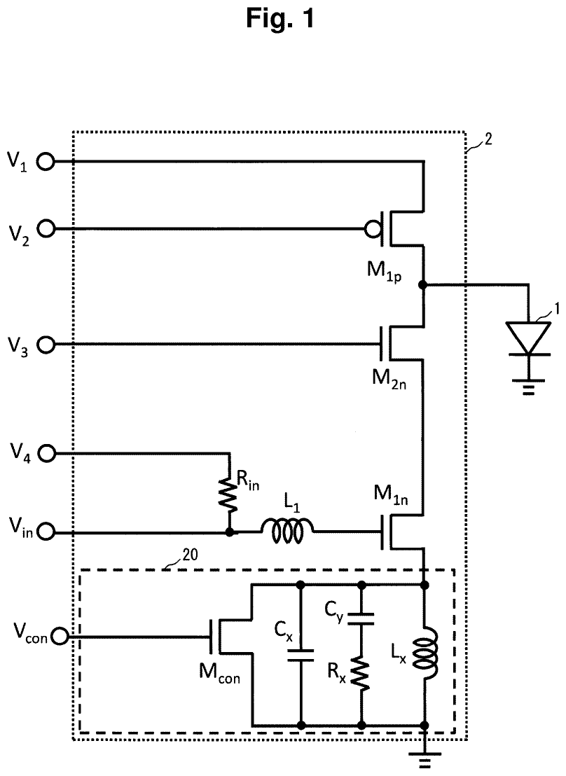

Hereinafter, examples of the present invention will be described with reference to the drawings. FIG. 1 is a circuit diagram illustrating a configuration of a DML driver according to a first example of the present invention. A DML driver 2 of the present example includes a PMOS transistor M₁ₚ having a gate connected to a bias voltage V₂ (first bias voltage), a source connected to a power supply voltage V₁ (first power supply voltage), and a drain connected to an anode of the LD 1, an NMOS transistor M₁ₙ, a NMOS transistor M₂ₙ having a gate connected to a bias voltage V₃ (third bias voltage), a drain connected to a drain of the PMOS transistor M₁ₚ and an anode of the LD 1, and a source connected to a drain of the NMOS transistor Mm, an inductor L₁ having one end to which a modulation signal Vᵢₙ is input, the other end connected to a gate of the NMOS transistor M₁ₙ, and a resistor Rᵢₙ having one end connected to a bias voltage V₄ (second bias voltage), and the other end being connected to one end of the inductor L₁, and an optical waveform compensation function unit 20 connected between the source of the NMOS transistor M₁ₙ and ground (second power supply voltage).

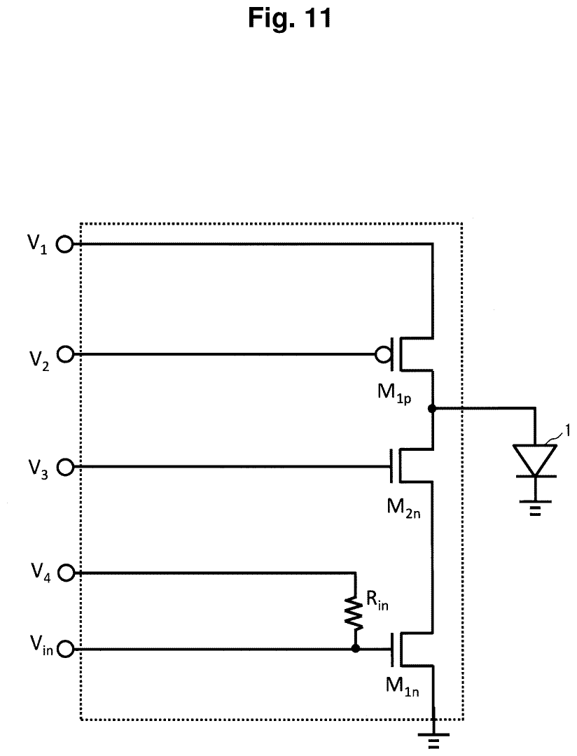

The magnitude relationship between respective voltages is V₁>V₂>V₃>V₄>GND (ground). In the present example, with respect to the circuit configuration of FIG. 11, the inductor L₁ is inserted between the modulation signal Vᵢₙ and the gate of the NMOS transistor M₁ₙ, and the optical waveform compensation function unit 20 is inserted between the source of the NMOS transistor M₁ₙ and the ground.

The optical waveform compensation function unit 20 includes an NMOS transistor M_{con} having a gate to which a control voltage V_{con} is input, a drain of which is connected to the source of the NMOS transistor M₁ₙ, and a source of which is connected to the ground, an inductor Lₓ having one end connected to the drain of the NMOS transistor M_{con} and the other end connected to the ground, a capacitor C_{y} having one end connected to the drain of the NMOS transistor M_{con}, a capacitor Cₓ having one end connected to the drain of the NMOS transistor M_{con} and the other end connected to ground, and a gain adjustment resistor Rₓ having one end connected to the other end of the capacitor C_{y} and the other end connected to ground.

The inductor Lₓ attenuates the gain of the DML driver 2 at high frequencies. The capacitors C_{y} and Cₓ increase the gain of the DML driver 2 at high frequencies. Since the impedance of the optical waveform compensation function unit 20 changes as the impedance of the NMOS transistor M_{con} changes according to the control voltage V_{con}, it is possible to adjust the frequency peaking amount by the inductor L₁. As a result, in the present example, it is possible to improve the group delay characteristic while improving the frequency characteristic of the transmission front end configured by the DML driver 2 and the LD 1.

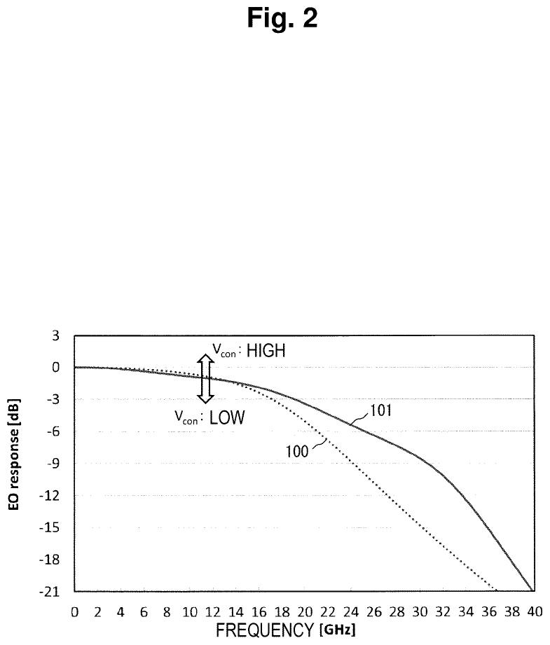

FIG. 2 illustrates results obtained by simulation of the Electrical-to-Optical (EO) response characteristics of the DML driver and the LD 1 for the conventional configuration and the present example. Reference numeral 100 in FIG. 2 indicates the EO response characteristic of the conventional configuration illustrated in FIG. 11, and reference numeral 101 indicates the EO response characteristic of the present example. As can be seen from FIG. 2, in the configuration of the present example, the frequency peaking effect by the inductor L₁ improves the band of the EO response characteristic as compared with the conventional circuit configuration.

In addition, in the present example, the frequency peaking amount by the inductor L₁ can be adjusted by increasing or decreasing the control voltage V_{con}, and the frequency peaking amount can be set to a frequency peaking amount according to the EO response characteristic for each individual LD 1. Specifically, increasing the control voltage V_{con} increases the frequency peaking amount, and decreasing the control voltage V_{con} decreases the frequency peaking amount.

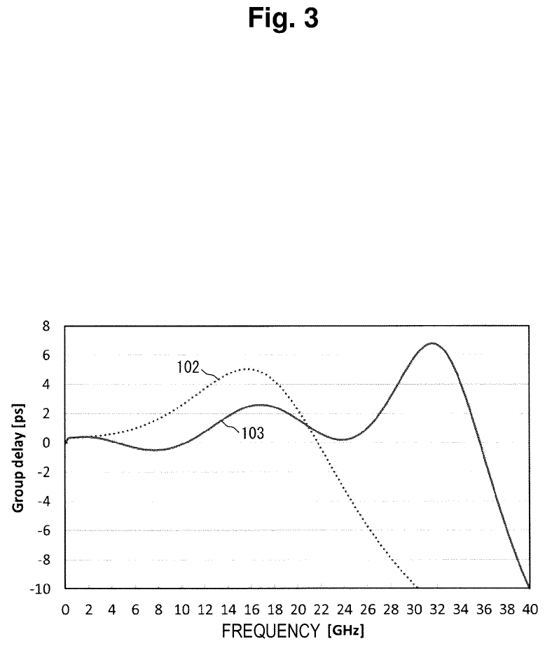

Next, FIG. 3 illustrates results obtained by simulating the group delay characteristics of the DML driver and the LD 1 in the conventional configuration and the present example. In FIG. 3, reference numeral 102 indicates a group delay characteristic of the conventional configuration, and reference numeral 103 indicates a group delay characteristic of the present example. In the conventional circuit configuration, the value of the group delay peaks around 16 GHz. On the other hand, in the circuit configuration of the present example, the value of the group delay in the vicinity of 16 GHz is a half or less of the conventional peak value by the optical waveform compensation function unit 20. Furthermore, comparing the value of the group delay of each frequency between the conventional circuit configuration and the circuit configuration of the present example, it can be seen that the value of the group delay can be reduced in the present example using the optical waveform compensation function unit 20.

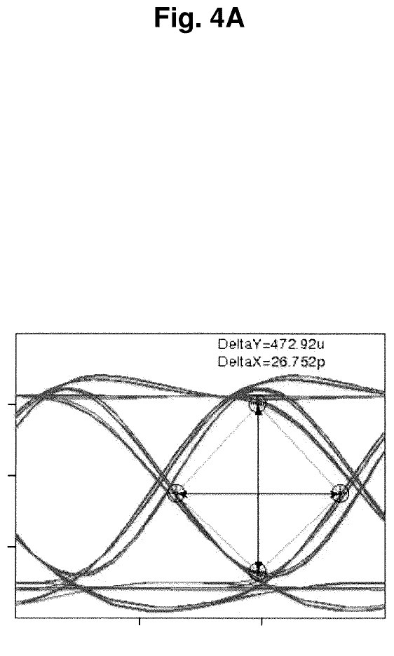

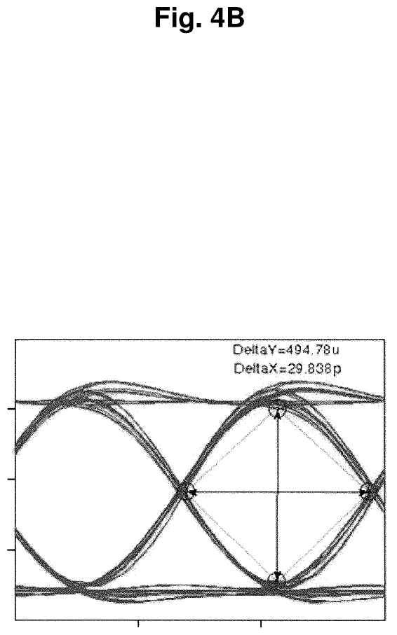

Next, FIG. 4A illustrates a result of obtaining the light output waveform of the LD 1 by simulation for the conventional configuration, and FIG. 4B illustrates a result of obtaining the light output waveform of the LD 1 by simulation for the configuration of the present example. The examples of FIGS. 4A and 4B illustrate a case where the Non Return to Zero (NRZ) signal light having a signal speed of 32 Gbps is output from the LD 1. The amplitude scale on the vertical axis is 200 μW/div, and the time scale on the horizontal axis is 20 ps/div. Comparing FIGS. 4A and 4B, it can be seen that the frequency peaking function by the inductor L₁ and the optical waveform compensation function unit 20 improve the eye opening in both the horizontal axis (time) direction and the vertical axis (amplitude) direction in the circuit configuration of the present example.

### Second Example

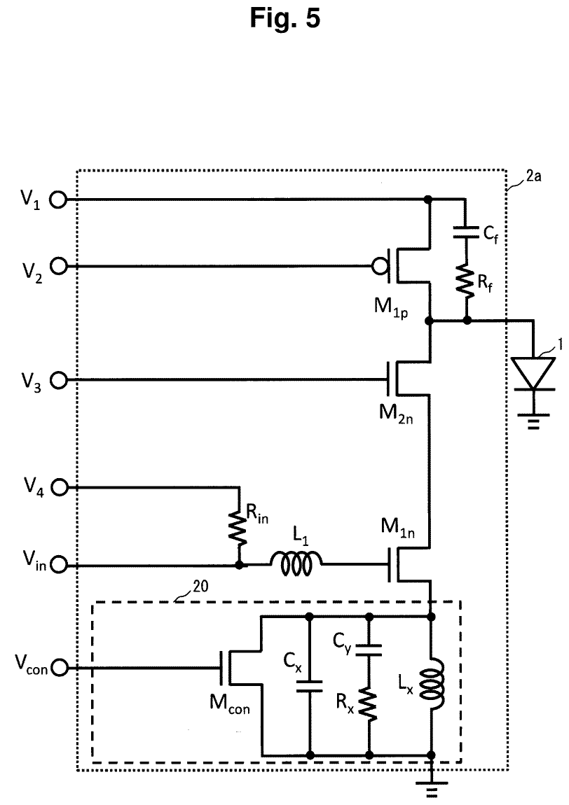

Next, a second example of the present invention will be described. FIG. 5 is a circuit diagram illustrating a configuration of a DML driver according to the second example of the present invention. In a DML driver 2a of the present example, a series connection element of a capacitor C_{f} and a resistor R_{f} is connected between the source and the drain of the PMOS transistor M₁ₚ with respect to the circuit configuration of the first example.

The capacitor C_{f} and the resistor R_{f} function as a high frequency filter. In a case where an excessive overshoot or undershoot is observed in the light output waveform of the LD 1, it is possible to suppress the overshoot and the undershoot of the light output waveform and shape the light output waveform by providing the capacitor C_{f} and the resistor R_{f}. As a result, in the present example, an effect of improving the eye opening in both the horizontal axis (time) direction and the vertical axis (amplitude) direction can be expected.

### Third Example

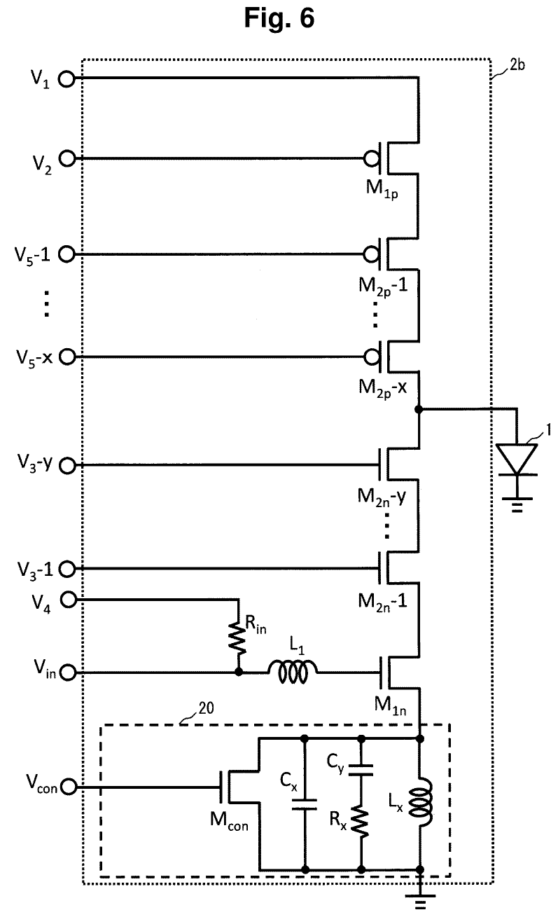

Next, a third example of the present invention will be described. FIG. 6 is a circuit diagram illustrating a configuration of a DML driver according to the third example of the present invention. A DML driver 2b of the present example includes the PMOS transistor M₁ₚ, the NMOS transistor M₁ₙ, one or a plurality of PMOS transistors M₂ₚ-1 to M₂ₚ-x having gates connected to bias voltages V₅-1 to V₅-x (fourth bias voltage) and cascode-connected between the drain of the PMOS transistor M₁ₚ and the anode of the LD 1, one or more NMOS transistors M₂ₙ-1 to M₂ₙ-y having gates connected to bias voltages V₃-1 to V₃-y (third bias voltage) and cascode-connected between the anode of the LD 1 and the drain of the NMOS transistor M₁ₙ, the inductor L₁, the resistor Rᵢₙ, and the optical waveform compensation function unit 20.

The magnitude relationship between respective voltages is V₁>V₂>V₅-1>. . . >V₅-x>V₃-y >. . . >V₃-1>V₄>GND (ground). In the cascode connection of the PMOS transistor, the source may be connected to the drain of the upper PMOS transistor, and the drain may be connected to the source of the lower PMOS transistor or the anode of the LD 1. In the cascode connection of the NMOS transistor, the source may be connected to the drain of the lower NMOS transistor, and the drain may be connected to the source of the upper NMOS transistor or the anode of the LD 1.

As described above, both the PMOS transistor and the NMOS transistor can adopt a multi-stage circuit configuration in order to prevent breakdown of the withstand voltage. The most advanced node is effective because the withstand voltage per transistor is reduced. Here, the PMOS transistors M₂ₚ-1 to M₂ₚ-x cascode-connected to the PMOS transistor M₁ₚ are set as an x stage, and the NMOS transistors M₂ₙ-1 to M₂ₙ-y cascode-connected to the NMOS transistor M₁ₙ are set as a y stage. Both x and y are set to 1 or more.

### Fourth Example

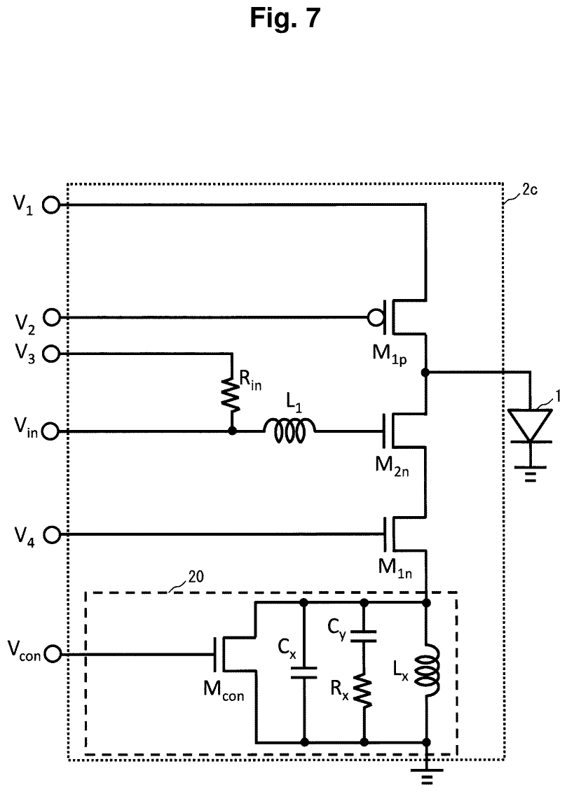

Next, a fourth example of the present invention will be described. FIG. 7 is a circuit diagram illustrating a configuration of a DML driver according to the fourth example of the present invention. A DML driver 2c of the present example includes the PMOS transistor M₁ₚ having a gate connected to the bias voltage V₂, a source connected to the power supply voltage V₁, and a drain connected to the anode of the LD 1, the NMOS transistor M₁ₙ having a gate connected to the bias voltage V₄, the NMOS transistor Man having a drain connected to the drain of the PMOS transistor M₁ₚ and the anode of the LD 1, and a source connected to the drain of the NMOS transistor M₁ₙ, the inductor L₁ having one end to which the modulation signal Vᵢₙ is input, and the other end connected to the gate of the NMOS transistor M₂ₙ, a resistor Rin having one end connected to the bias voltage V₃, and the other end connected to one end of the inductor L₁, and the optical waveform compensation function unit 20 connected between the source of the NMOS transistor M₁ₙ and the ground.

In the first example, the modulation signal Vᵢₙ is input to the gate of the NMOS transistor M₁ₙ via the inductor L₁. In the present example, the modulation signal Vᵢₙ is input to the gate of the NMOS transistor M₂ₙ via the inductor L₁. As a result, in the present example, the current flowing from the PMOS transistor M₁ₚ to the NMOS transistors M₂ₙ and M₁ₙ side can be adjusted by adjusting the bias voltage V₄ applied to the gate of the NMOS transistor M₁ₙ.

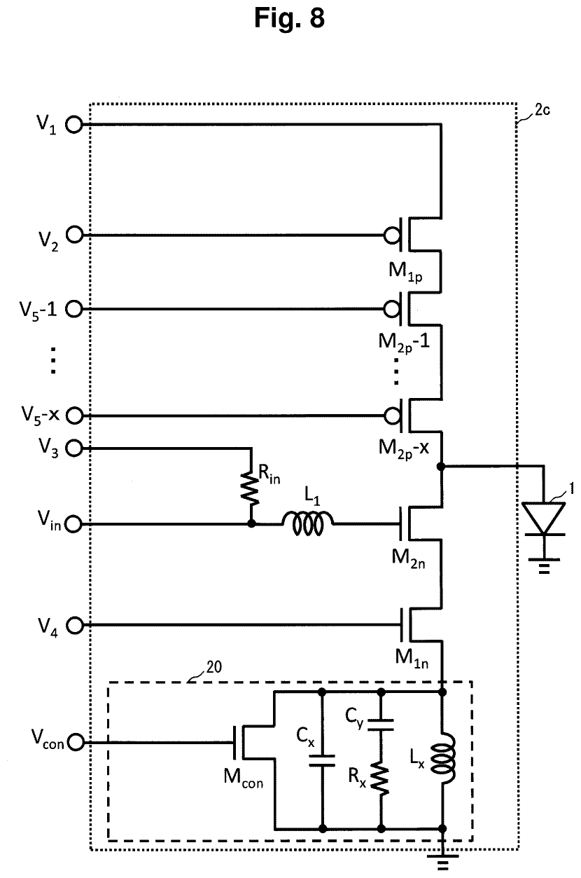

Similarly to the third example, x stages (x is an integer of 1 or more) of the PMOS transistors M₂ₚ-1 to M₂ₚ-x cascode-connected to the PMOS transistor M₁ₚ may be provided. A configuration in this case is illustrated in FIG. 8.

In addition, in the present example, the NMOS transistor Man cascode-connected to the NMOS transistor M₁ₙ is set to one stage (y=1), but the NMOS transistors M₂ₙ-1 to M₂ₙ-y of a plurality of stages may be connected as described in the third example (y≥2). In this case, the inductor L₁ may be connected between the gate of any one NMOS transistor M₂ₙ-k (k is any one of 1 to y) among the plurality of stages of NMOS transistors M₂ₙ-1 to M₂ₙ-y and the modulation signal Vᵢₙ, and the resistor Rᵢₙ may be connected between the bias voltage V₃-k to be applied to the NMOS transistor M₂ₙ-k and the inductor L₁. In addition, the capacitor C_{f} and the resistor R_{f} may be applied to the present example.

### Fifth Example

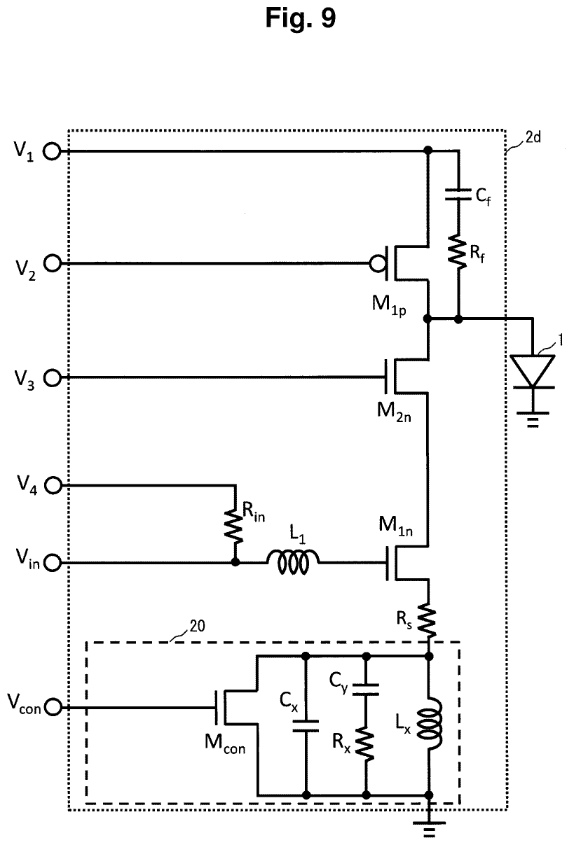

Next, a fifth example of the present invention will be described. FIG. 9 is a circuit diagram illustrating a configuration of a DML driver according to the fifth example of the present invention. In a DML driver 2d of the present example, a resistor Rₛ is inserted between the source of the NMOS transistor M₁ₙ and the drain of the NMOS transistor M_{con} of the optical waveform compensation function unit 20 with respect to the DML driver 2a of the second example. As a result, in the present example, the linearity of the DML driver 2d can be improved, and the DML driver 2d can be operated more linearly with respect to the modulation signal Vᵢₙ.

In FIG. 9, the resistor Rₛ is applied to the second example, but the resistor Rₛ may be applied to the first, third, and fourth examples.

### Sixth Example

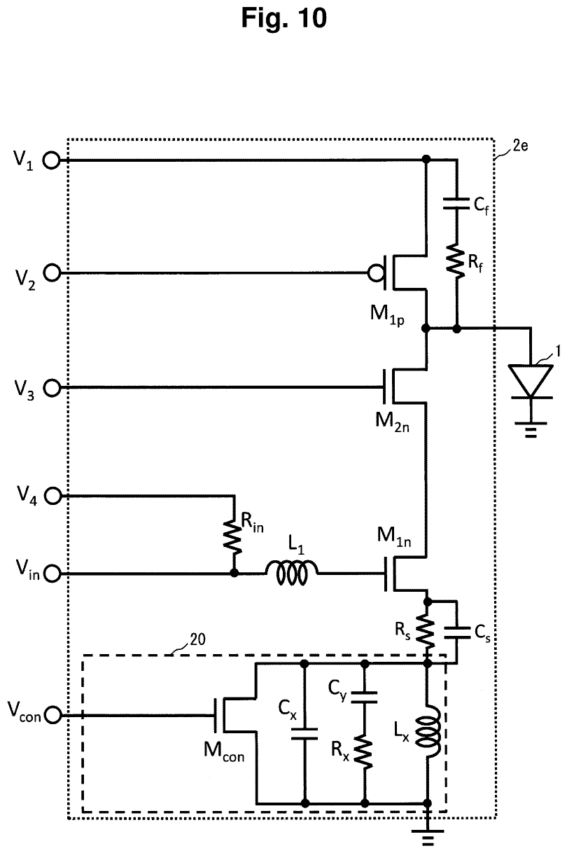

Next, a sixth example of the present invention will be described. FIG. 10 is a circuit diagram illustrating a configuration of a DML driver according to the sixth example of the present invention. A DML driver 2e of the present example is obtained by connecting a capacitor Cₛ in parallel with the resistor Rs to the DML driver 2d of the fifth example. As a result, in the present example, the band at the high frequency of the transmission front end configured by the DML driver 2e and the LD 1 can be improved as compared with the fifth embodiment.

In FIG. 10, the resistor Rₛ and the capacitor Cₛ are applied to the second example, but the resistor Rₛ and the capacitor Cₛ may be applied to the first, third, and fourth examples.

When there is no problem in the withstand voltage of the NMOS transistor, the NMOS transistors Man and M₂ₙ-1 to M₂ₙ-y in the first to third, fifth, and sixth examples may be omitted, and the drain of the NMOS transistor M₁ₙ and the anode of the LD 1 may be connected. In this case, the bias voltages V₃ and V₃-1 to V₃-y are unnecessary.

In addition, in the third example, when there is no problem in the withstand voltage of the PMOS transistor, the PMOS transistors M₂ₚ-1 to M₂ₚ-x may be omitted, and the drain of the PMOS transistor M₁ₚ and the anode of the LD 1 may be connected as in the first, second, and fourth to sixth examples. In this case, the bias voltages V₅-1 to V₅-x are unnecessary.

Furthermore, in the first to sixth examples, an example is illustrated in which MOS transistors are used as the transistors M₁ₚ, M₂ₚ-1 to M₂ₚ-x, M₁ₙ, M₂ₙ, M₂ₙ-1 to M₂ₙ-y, and M_{con}. However, PNP bipolar transistors may be used as the transistors M₁ₚ and M₂ₚ-1 to M₂ₚ-x, and NPN bipolar transistors may be used as the transistors M₁ₙ, M₂ₙ, M₂ₙ-1 to M₂ₙ-y, and M_{con}. In a case where the bipolar transistor is used, the gate may be replaced with the base, the drain may be replaced with the collector, and the source may be replaced with the emitter in the description of the first to sixth examples.

### Industrial Applicability

The present invention can be applied to a technique of directly modulating an optical output of an LD.

### REFERENCE SIGNS LIST

1 LD
2, 2a to 2e DML DRIVER
20 Optical waveform compensation function unit
M₁ₚ, M₂ₚ-1 to M₂ₚ-x PMOS transistor
M₁ₙ, M₂ₙ, M₂ₙ-1 to M₂ₙ-y, M_{con} NMOS transistor
L₁, Lₓ Inductor
Rᵢₙ, Rₓ, R_{f}, Rₛ Resistor
C_{y}, Cₓ, C_{f}, Cₛ Capacitor

1-8. (canceled)

9. A DML driver comprising:
a first transistor having a gate or base connected to a first bias voltage, a source or emitter connected to a first power supply voltage, and a drain or collector connected to an anode of a laser diode;
a second transistor having a drain or collector connected to the anode of the laser diode;
a first inductor to which a modulation signal is configured to be input at a first end, and a second end of the first inductor being connected to a gate or base of the second transistor;
a first resistor having a first end connected to a second bias voltage and a second end connected to the first end of the first inductor; and
an optical waveform compensation function circuit connected between a source or emitter of the second transistor and a second power supply voltage, wherein
the optical waveform compensation function circuit includes:
a third transistor in which a control voltage is configured to be input to a gate or base, a drain or collector is connected to the source or emitter of the second transistor, and a source or emitter is connected to the second power supply voltage;
a second inductor having a first end connected to the drain or collector of the third transistor and a second end connected to the second power supply voltage;
a first capacitor having a first end connected to the drain or collector of the third transistor;
a second capacitor having a first end connected to the drain or collector of the third transistor and a second end connected to the second power supply voltage; and
a second resistor having a first end connected to a second end of the first capacitor and a second end connected to the second power supply voltage.

10. The DML driver according to claim 9, further comprising:
a fourth transistor having a gate or base connected to a third bias voltage and cascode-connected between the anode of the laser diode and the drain or collector of the second transistor.

11. The DML driver according to claim 10, further comprising:
a fifth transistor having a gate or base connected to a fourth bias voltage and cascode-connected between the drain or collector of the first transistor and the anode of the laser diode.

12. The DML driver according claim 9, further comprising:
a third capacitor having a first end connected to the first power supply voltage; and
a third resistor having a first end connected to a second end of the third capacitor and a second end connected to the drain or collector of the first transistor.

13. The DML driver according claim 9, further comprising:
a third resistor between the source or emitter of the second transistor and the optical waveform compensation function circuit.

14. The DML driver according to claim 13, further comprising:
a third capacitor connected in parallel with the third resistor.

15. A DML driver comprising:
a first transistor having a gate or base connected to a first bias voltage, a source or emitter connected to a first power supply voltage, and a drain or collector connected to an anode of a laser diode;
a second transistor having a gate or base connected to a second bias voltage;
a third transistor cascode-connected between the anode of the laser diode and a drain or collector of the second transistor;
a first inductor to which a modulation signal is configured to be input at a first end, and a second end of the first inductor being connected to a gate or base of the third transistor;
a first resistor having a first end connected to a third bias voltage and a second end connected to the first end of the first inductor; and
an optical waveform compensation function circuit connected between a source or emitter of the second transistor and a second power supply voltage, wherein
the optical waveform compensation function circuit includes:
a fourth transistor in which a control voltage is input to a gate or base, a drain or collector is connected to the source or emitter of the second transistor, and a source or emitter is connected to the second power supply voltage;
a second inductor having a first end connected to the drain or collector of the fourth transistor and a second end connected to the second power supply voltage;
a first capacitor having a first end connected to the drain or collector of the fourth transistor;
a second capacitor having a first end connected to the drain or collector of the fourth transistor and a second end connected to the second power supply voltage; and
a second resistor having a first end connected to a second end of the first capacitor and a second end connected to the second power supply voltage.

16. The DML driver according to claim 15, further comprising:
a fifth transistor having a gate or base connected to a fourth bias voltage and cascode-connected between the drain or collector of the first transistor and the anode of the laser diode.

17. The DML driver according claim 15, further comprising:
a third capacitor having a first end connected to the first power supply voltage; and
a third resistor having a first end connected to a second end of the third capacitor and a second end connected to the drain or collector of the first transistor.

18. The DML driver according claim 15, further comprising:
a third resistor between the source or emitter of the second transistor and the optical waveform compensation function circuit.

19. The DML driver according to claim 18, further comprising:
a third capacitor connected in parallel with the third resistor.
